(19) United States
(12) Patent Application Publication
(10) Pub. No.: US 2017/0125282 A1
(43) Pub. Date: May 4, 2017

(54) FILM FORMING APPARATUS

(71) Applicant: TOKYO ELECTRON LIMITED, Tokyo (JP)

(72) Inventors: Takahito UMEHARA, Oshu-shi (JP); Masayuki HASEGAWA, Oshu-shi (JP); Kiichi TAKAHASHI, Oshu-shi (JP); Yuya SASAKI, Oshu-shi (JP)

(21) Appl. No.: 15/297,383

(22) Filed: Oct. 19, 2016

(30) Foreign Application Priority Data
Oct. 28, 2015 (JP) 2015-211946

(51) Int. Cl. H01L 21/687; C23C 16/458; C23C 16/455

(52) U.S. Cl. CPC H01L 21/68785; C23C 16/45544; C23C 16/4584; C23C 16/4586; H01L 21/68764; H01L 21/68771

(57) ABSTRACT

A film forming apparatus for forming films on substrates mounted on a rotary table by rotating the rotary table and causing the substrates to sequentially pass through areas to which process gases are supplied, including: recess portions formed in one surface of the rotary table along a circumferential direction and configured to accommodate the substrates; mounting portions disposed with the recess portions and configured to support regions of the substrates closer to centers than peripheral edge portions thereof; groove portions formed within the recess portions so as to surround the mounting portions; communication paths formed so as to extend from regions of the groove portions existing at a side of a rotational center of the rotary table toward an external area of the recess portions; and an exhaust port through which an interior of a vacuum container is vacuum-exhausted.

### CROSS-REFERENCE TO RELATED APPLICATION

This application claims the benefit of Japanese Patent Application No. 2015-211946, filed on Oct. 28, 2015, in the Japan Patent Office, the disclosure of which is incorporated herein in its entirety by reference.

### TECHNICAL FIELD

The present disclosure relates to an apparatus which forms a film on a substrate by rotating a rotary table within a vacuum container so that the substrate mounted on the rotary table sequentially passes through a supply area of a raw material gas and a supply area of a reaction gas reacting with the raw material gas.

### BACKGROUND

A so-called atomic layer deposition (ALD) method is known as a method of forming a thin film such as a silicon oxide (SiO₂) film or the like on a substrate such as a semiconductor wafer or the like (hereinafter referred to as a “wafer”). As an apparatus for implementing the ALD method, there is known an apparatus which revolves a plurality of wafers disposed on a rotary table within a vacuum container so that the wafers sequentially pass through a supply area of a raw material gas and a supply area of a reaction gas reacting with the raw material gas. Recesses into which the wafers are respectively accommodated and held are formed in the rotary table. The recesses are formed in a size slightly larger than the size of the wafers in a plan view so as to leave a clearance in an outer periphery of each of the wafers (so as to removably hold the wafers).

It is known that, immediately after the wafers are transferred into the respective recesses of the rotary table by an external transfer arm, due to unevenness of an in-plane temperature during a heating process, each of the wafers is warped so that a central portion thereof is swollen more than the peripheral edge portion thereof and further that the warp is reduced as the uniformity of the in-plane temperature increases. The rotary table is rotated. Due to the centrifugal force generated by the rotation of the rotary table, the wafer is moved toward the outer periphery of the rotary table within the respective recess just as much as the clearance. In this way, the wafer is moved while going back into a flat state from the warped state. Thus, the peripheral edge portion of the wafer is moved so as to rub the bottom surface of the recess, which results in the occurrence of particles.

For that reason, there has been proposed a configuration in which a wafer mounting stand having a plan-view size smaller than the size of the wafer is installed on the bottom surface of the recess. With this configuration, the friction between the peripheral edge portion of the wafer and the bottom surface of the recess is suppressed, which makes it possible to suppress the occurrence of particles. However, the present inventors have found that, in the case of performing a process in which the revolution number of the rotary table is high or a process in which the pressure of a process atmosphere is high, there is generated a phenomenon that the film thickness locally increases in a portion of the peripheral edge portion of the wafer. The present inventors assume that this phenomenon occurs because a dense gas locally stays within a groove existing around the mounting table and goes around the surface of the wafer. A demand has existed to form a film so that the film thickness is relatively large at the side of the center of the wafer and is reduced toward the side of the peripheral edge of the wafer and so that the uniformity of the film thickness increases in the circumferential direction of the wafer. However, if the circulation of the dense gas toward the surface of the wafer occurs as described above, a variation in the film thickness is generated in the circumferential direction of the peripheral edge portion of the wafer. Thus, there is a fear that it is impossible to sufficiently meet the demand.

### SUMMARY

Some embodiments of the present disclosure provide a film forming apparatus capable of ensuring good film thickness uniformity at a peripheral edge portion of a substrate in a circumferential direction of the substrate, when a film forming process is performed with respect to the substrate mounted on a rotary table by rotating the rotary table within a vacuum container.

According to one embodiment of the present disclosure, there is provided a film forming apparatus for forming films on a plurality of substrates mounted on a rotary table by rotating the rotary table within a vacuum container and causing the substrates to sequentially pass through areas to which process gases are supplied, including: a plurality of recess portions formed in one surface of the rotary table along a circumferential direction and configured to accommodate the plurality of substrates; a plurality of mounting portions disposed within the recess portions and configured to support regions of the substrates closer to centers than peripheral edge portions thereof; a plurality of groove portions formed within the recess portions no as to surround the plurality of mounting portions; a plurality of communication paths formed so as to extend from regions of the groove portions existing at a side of a rotational center of the rotary table when viewed from a center of each of the plurality of mounting portions, toward an external area of the recess portions, the plurality of communication paths composed of communication grooves or communication holes; and an exhaust port through which an interior of the vacuum container is vacuum-exhausted, wherein the external area is an annular groove portion formed around the mounting portion inside the other recess portion adjoining one of the plurality of recess portions or an outside of an outer peripheral edge of the rotary table.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view illustrating a film forming apparatus according to an embodiment of the present disclosure.

FIG. 2 is a transverse plan view illustrating the film forming apparatus according to an embodiment of the present disclosure.

FIG. 3 is a plan view illustrating a rotary table of the film forming apparatus.

FIG. 4 is a perspective view illustrating a portion of the rotary table.

FIG. 5 is a vertical sectional view illustrating the rotary table in a cross section taken along a radial direction.

FIG. 6 is a vertical sectional view illustrating the rotary table in a cross section taken along line I-I′.

FIG. 7 is an explanatory view illustrating a recess of the rotary table in association with a film thickness distribution of a water in a reference example.

FIG. 8 is an explanatory view schematically illustrating a gas flow within a recess of the rotary table in a reference example.

FIG. 9 is an explanatory view schematically illustrating a gas flow within a recess of the rotary table in an embodiment of the present disclosure.

FIG. 10 is a plan view illustrating a portion of a rotary table in another embodiment of the present disclosure.

FIG. 11 is a plan view illustrating a portion of a rotary table in a further embodiment of the present disclosure.

FIG. 12 is a characteristic diagram illustrating an in-plane film thickness distribution of a wafer in an embodiment of the present disclosure and in a reference example.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

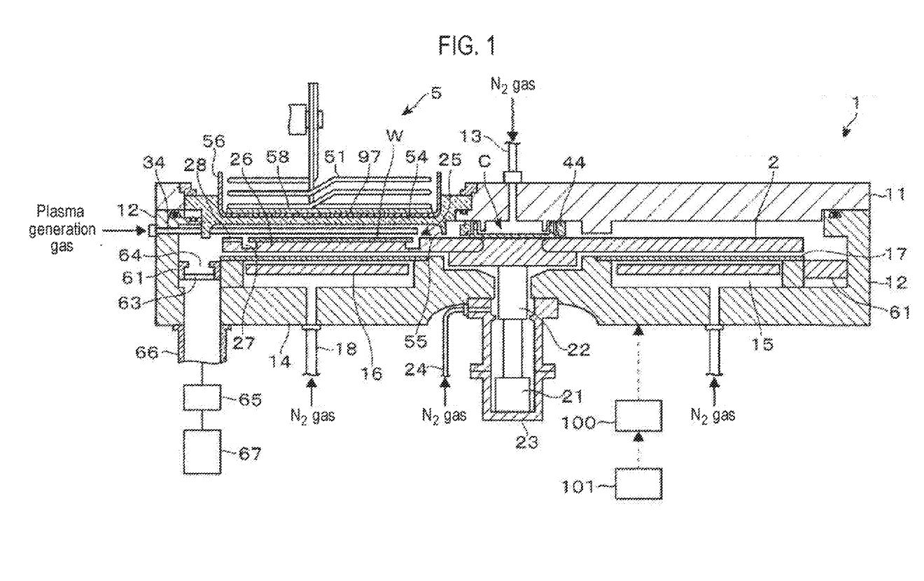

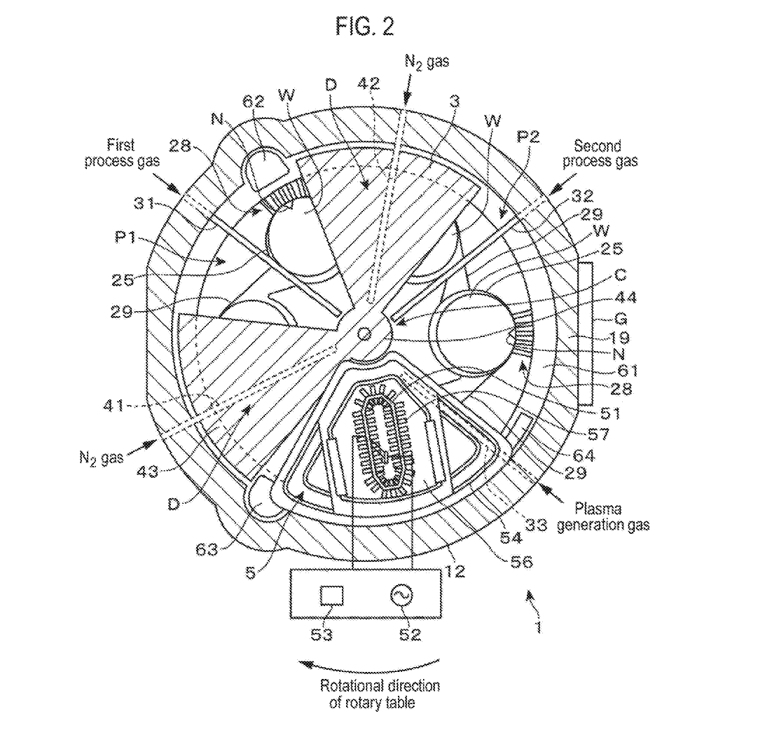

A film forming apparatus according to an embodiment of the present disclosure will be described with reference to FIGS. 1 and 2 which are a vertical sectional view and a transverse plan view. The film forming apparatus includes a vacuum container 1 having a substantially circular plan-view shape and a horizontal circular rotary table 2 installed within the vacuum container 1 and made of, for example, quartz. The rotary table has a rotation axis at the center of the vacuum container 1. The film forming apparatus performs a film forming process by supplying process gases to wafers W mounted on the rotary table 2. Symbol N in FIG. 2 designates a notch which is a cutout formed in a peripheral edge portion of each of the wafers W

Reference numerals 11 and 12 designate a top plate and a container body, respectively, which constitute the vacuum container 1. A separation gas supply pipe 13 for supplying a nitrogen (N₂) gas as a separation gas in order to restrain different process gases from being mixed with each other in a central area C within the vacuum container 1 is connected to a central portion of an upper surface of the top plate 11.

An annular depression 15 is formed in a bottom surface 14 of the container body 12 along a circumferential direction of the vacuum container 1 (see FIG. 1). A heater unit 16 as a heating mechanism is installed within the depression 15. The heater unit 16 is configured to heat the wafers W mounted on the rotary table 2 to a predetermined film forming temperature, for example, 620 degrees C., through the rotary table 2. Reference numeral 17 in FIG. 1 designates a cover which covers the depression 15. Reference numeral 18 in FIG. 1 designates a supply pipe configured to supply a purge gas for purging the interior of the depression 15.

A rotating mechanism 21 configured to rotate the rotary table 2 clockwise through a vertical rotary shaft 22 is installed below the central portion of the rotary table 2. Reference numeral 23 in FIG. 1 designates a case which accommodates the rotary shaft and the rotating mechanism 21. Reference numeral 24 in FIG. 1 designates a purge gas supply pipe for supplying an N₂ gas as a purge gas into the case 23.

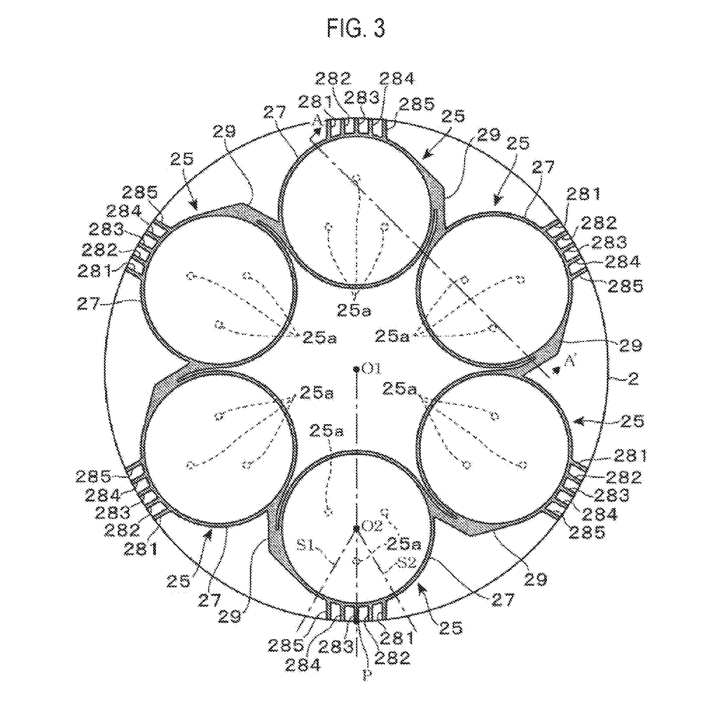

FIG. 3 illustrates one surface (front surface) of the rotary table 2. A recess portion or a groove portion is formed in one surface of the rotary table 2 so that a stepped portion is formed. In FIG. 3, an area where the recess portion or the groove portion is formed and has a height smaller than the height of a surrounding area, is indicated by a gray scale to assure easier identification of the respective portions. Circular recess portions 25 are formed in the front surface of the rotary table 2 at six points along a rotational direction (circumferential direction) of the rotary table 2. The circular wafers W are accommodated and held into the respective recess portions 25. Each of the recess portions 25 is formed so that, in a plan view, the diameter thereof becomes larger than the diameter of the wafers W in order to form a gap area (clearance) between the outer periphery of each of the recess portions 25 and the outer periphery of each of the wafers W. Specifically, the diameter of the wafers W and the diameter of the recess portions 25 are, for example, 300 mm and 302 mm, respectively. In addition, the diameter of the rotary table 2 is set at, for example, about 1,000 mm.

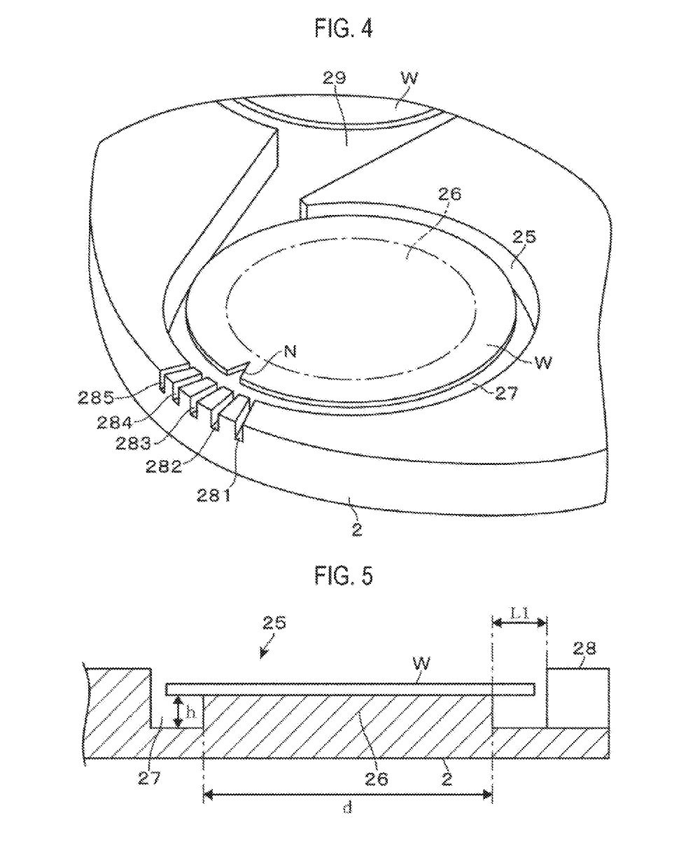

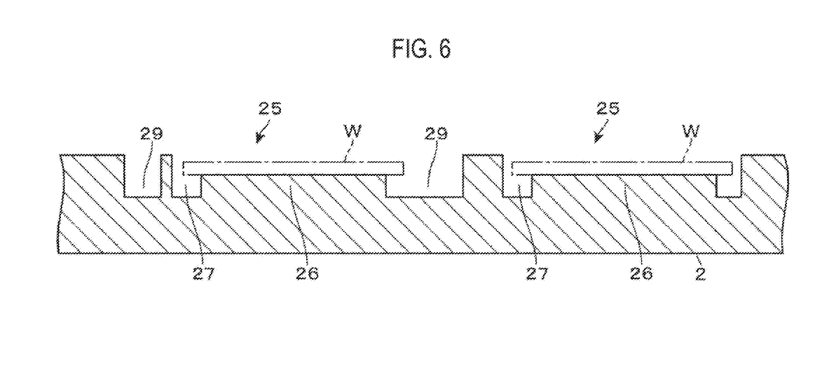

FIG. 4 is a perspective view of the recess portion 25. FIG. 5 is a vertical sectional view of the recess portion 25 taken along the radial direction of the rotary table 2. FIG. 6 is a sectional view taken along line I-I′ in FIG. 3. The rotary table 2 will be described again with reference to these figures. The peripheral edge portion of the bottom portion of the recess portion 25 is further depressed downward to thereby form an annular groove portion 27. A bottom portion of the recess portion 25 surrounded by the annular groove portion 7 is defined as a circular mounting portion 26 having a horizontal upper end surface. In a plan view, the center of the mounting portion 26 and the center of the recess portion 25 coincide with each other. The diameter of the mounting portion 26 is smaller than the diameter of the wafer W.

With the configuration, when the wafer W is mounted on the mounting portion 26, as illustrated in FIGS. 5 and 6, the area of the wafer W existing closer to the central portion than the peripheral edge portion is supported by the mounting portion 26, and the peripheral edge portion of the wafer W is spaced apart from the bottom surface of the recess portion 25. The reason for forming the mounting portion 26 and the annular groove portion 27 so that the wafer W is mounted as described above is to prevent friction between the thermally warped wafer W and the bottom surface of the recess portion 25 as discussed in the background section of the present disclosure. In FIG. 3, reference numeral 25a designates through-holes formed in the mounting portion 26. Three lift pins (not shown) for pushing up and lifting the wafer W from below are configured to protrude or retract through the respective through-holes.

The height h of the mounting portion 26 illustrated in FIG. 5 is, for example, 0.1 mm to 1.0 mm, and is set so that the surface of the rotary table 2 is positioned a little higher than the surface of the wafer W mounted on the mounting portion 26. The diameter d of the mounting portion 26 is, for example, 297 mm. The width of the a groove portion 27 (the dimension between the inner wall surface of the recess portion 25 and the outer wall surface of the mounting portion 26) L1 is, for example, 3 mm. In FIG. 5, the width L1 and the height h are exaggerated and depicted on a large scale.

For example, five linear groove portions 28 having a small width, which are communication paths for bringing a space existing within the recess portion 25 around the mounting portion 26 and a space existing outside the rotary table 2 into communication with each other, are formed in a corresponding relationship with each of the recess portion 25. These five linear groove portions 28 (often designated by 281 to 285) are cutouts extending from the inner wall surface of the recess portion 25 to the outer periphery of the rotary table 2. When viewed from the center of the recess portion 25, the five linear groove portions 28 are formed in an edge area of the recess portion 25 existing at the opposite side from the rotational center (designated by O1 in FIG. 3) of the rotary table 2 and are disposed in a spaced-apart relationship in the circumferential direction of the rotary table 2. When a point where a straight line A passing through the rotational center O1 of the rotary table 2 and the center O2 of the recess portion 25 intersects the outer periphery of the rotary table 2 is assumed to be P (see FIG. 3), the edge area is an area between a straight line S1 which forms an opening angle of 30 degrees from the center O2 of the recess portion 25 to the left side of the point P and a straight line S2 which forms an opening angle of 30 degrees from the center O2 of the recess portion 25 to the right side of the point P.

Six connection groove portions 29 are formed in the rotary table 2. The connection groove portions 29 are formed in a mutually spaced-apart relationship in the circumferential direction of the rotary table 2 so that, with respect to the recess portions 25 adjoining each other in the rotational direction of the rotary table 2, each of the connection groove portions 29 interconnects the recess portion existing at the downstream side of the rotational direction to the recess portion 25 existing at the upstream side of the rotational direction. One end portion of each of the connection groove portions 29 is formed so that, when viewed from the center O2 of the recess portion 25 existing at the downstream side of the rotational direction, a portion of the annular groove portion 27 of the recess portion 25 existing at the side of the rotational center O1 of the rotary table 2 is drawn toward the upstream side of the rotational direction of the rotary table 2. The other end portion of each of the connection groove portions 29 is formed so that, when viewed from the center O2 of the recess portion 25 existing at the upstream side of the rotational direction, a portion of the annular groove portion 27 of the recess portion 25 existing at the opposite side from the rotational center O1 of the rotary table 2 is drawn toward the downstream side of the rotational direction of the rotary table 2. By forming the connection groove portions 29 in this way, the recess portions 25 adjoining each other the rotational direction are connected to each other.

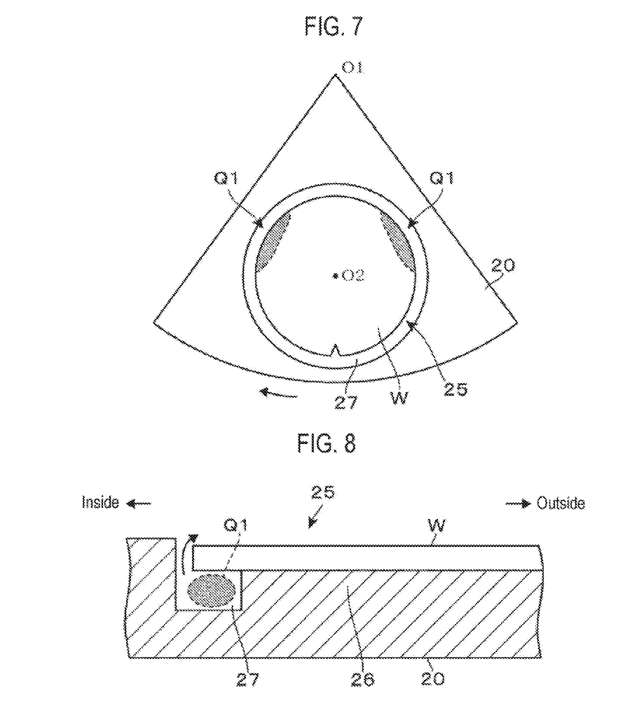

The reason for forming the connection groove portions 29 will be described with reference to FIG. 7 and FIGS. 7 and 8 illustrate a state in which a film forming process is performed using a rotary table 20 not provided with the connection groove portions 29. The present inventors have found that, in a film forming process, when viewed from the center O2 of the recess portion 25 toward the rotational center O1 of the rotary table 20, as illustrated in FIG. 7, process gas stagnations Q1 are formed in areas spaced apart in the left-right direction at the front side (the side of the rotational center O1) of the annular groove portion 27, whereby the concentration of the process gas increases in the areas. That is to say, during the film forming process, a relatively large difference in the concentration of the process gas is generated in the respective portions of the annular groove portion 27 along the circumferential direction. As illustrated in FIG. 8, the process gas, which forms the process gas stagnations Q1, goes around the peripheral edge portion of the surface of the wafer W. Thus, on the surface of the wafer W, the concentration of the process gas in the peripheral edge portion where the going-around of the process gas is generated becomes higher than the concentration of the process gas in other areas. As a result, it is considered that the uniformity of a film thickness distribution in the peripheral edge portion of the surface of the wafer W in the circumferential direction of the wafer W deteriorates.

The connection groove portions 29 of the rotary table 2 are to guide the process gas, which forms the process gas stagnations Q1 in the annular groove portion 27 of the recess portion 25 at the downstream side of the rotational direction, toward a point of the annular groove portion 27 of the recess portion 25 existing at the upstream side of the rotational direction, in which the process gas stagnations Q1 are not formed (namely a point in which the concentration of the process gas is low). It is therefore possible to prevent the process gas of the process gas stagnations Q1 from going around the surface of the wafer W.

Referring back to FIGS. 1 and 2, other parts of the film forming apparatus will be described. Reference numeral 19 in FIG. 2 designates a wafer transfer gate formed in the sidewall of the process vessel 1. The transfer gate 19 is opened and closed by a gate valve G. A transfer mechanism (not shown) of the wafer W moves into and out of the process vessel 1 through the transfer gate 19. Lift pins(not shown) for lifting up the wafer W from below through the through-holes 25a of the recess portion 25 described above are installed below the rotary table 2 at a position facing the transfer gate 19. The lift pins perform delivery of the wafer W between the wafer transfer mechanism and the recess portion 25.

As illustrated in FIG. 2, in positions facing regions through which the recess portions 25 pass, five nozzles 31, 32, 33, 41 and 42 made of, for example, quartz, are radially disposed in a mutually spaced-apart relationship along the circumferential direction of the vacuum container 1. In this example, in the clockwise direction (the rotational direction of the rotary table 2) from the transfer gate 19 described above, a plasma generation gas nozzle 33, a separation gas nozzle 41, a first process gas nozzle 31, a separation gas nozzle 42 and a second process gas nozzle 32 are disposed in the named order. A plasma generation part 5, which will be described later, is installed above the plasma generation gas nozzle 33.

The nozzles 31, 32, 33, 41 and 42 are connected to respective gas supply sources (not shown) which supply gases to the respective nozzles via flow rate control valves. The first process gas nozzle 31 is connected to a supply source of a raw material gas as a first process gas containing silicon (Si), for example, a 3DMAS (tris(dimethylamino)silane: SiH[N(CH₃)₂]₃) gas. The second process gas nozzle 32 is connected to a supply source of a reaction gas as a second process gas reacting with the raw material gas, for example, a mixed gas of an ozone (O₃) gas and an oxygen (O₂) gas. The plasma generation gas nozzle 33 is connected to a supply source of a plasma generation gas which is, for example, a mixed gas of an argon (Ar) gas and an O₂ gas. The separation gas nozzles 41 and 42 are respectively connected to supply sources of a nitrogen (N₂) gas which is a separation gas. For example, in lower surfaces of the nozzles 31, 32, 33, 41 and 42, gas injection holes (not shown) are formed at multiple points along the radial direction of the rotary table 2.

Areas existing below the process gas nozzles 31 and 32 are respectively defined as a first process area P1 where a first process gas is adsorbed onto the wafer W and a second process area P2 where a component of the first process gas adsorbed onto the wafer W reacts with a second process gas. Areas existing below the separation gas nozzles 41 and 42 are defined as separation areas D where the first process area P1 and the second process area P2 are separated. As illustrated in FIG. 2, protrusion portions 43 having a substantially fan-like shape are installed in the top plate 11 of the vacuum container 1 in the separation areas D. The separation gas nozzles 41 and 42 are installed to be embedded in the respective protrusion portions 43.

Thus, first ceiling surfaces (lower surfaces of the protrusion portions 43) having a low height and serving to prevent the process gases from being mixed with each other are disposed at the opposite sides of the separation gas nozzles 41 and 42 in the circumferential direction of the rotary table 2. Second ceiling surfaces higher than the first ceiling surfaces are disposed at the opposite sides of the first ceiling surfaces in the circumferential direction. In order to prevent the process gases from being mixed with each other, peripheral edge portions of the protrusion portions 43 (portions of the protrusion portions 43 existing at the side of the outer periphery of the vacuum container 1) are bent in an L-like shape so that the peripheral edge portions of the protrusion portions 43 are located opposite of the outer end surface of the rotary table 2 and are slightly spaced apart from the container body 12. A projection portion 44 projecting downward in a ring shape is formed in the central portion of the lower surface of the top plate 11 in order to prevent the process gases from being mixed with each other in the central portion of the low surface of the top plate 11. The lower surface of the projection portion 44 is formed to continuously extend with the lower surfaces of the protrusion portions 43.

The plasma generation part 5 includes an antenna 51 formed of a metal wire and wound in a coil shape. Reference numeral 52 in FIG. 2 designates a high-frequency power source. The high-frequency power source 52 is configured to supply high-frequency power to the antenna 51. A matcher 53 is installed between the high-frequency power source 52 and the antenna 51. Reference numeral 54 in FIG. 2 designates a cup-shaped housing. The housing 54 is configured to close an opening portion opened in a fan-like shape in a plan view at the upper side of the plasma generation gas nozzle 33 and is configured to store the antenna 51. Reference numeral 55 in FIGS. 1 and 2 designates a gas restricting projection for preventing the N₂ gas or the second process gas from entering an area below the housing 54. The projection 55 is formed along the peripheral edge portion of the housing 54. The plasma generation gas nozzle 33 is installed to extend from the outside of the projection 55 through the projection 55 and to extend into an area surrounded by the projection 55.

A box-shaped Faraday shield 56 opened at the upper surface side thereof is installed between the housing 54 and the antenna 51. The Faraday shield 56 is made of an electrically conductive material and is grounded. Slits 57 are formed in the bottom surface of the Faraday shield 56 in order to allow the magnetic field, among the electric field and the magnetic field (electromagnetic field) generated from the antenna 51, to reach the wafer W while preventing the electric field component from moving downward. Reference numeral 58 in the figures designates an insulation plate. The insulation plate 58 provides insulation between the Faraday shield 56 and the antenna 51.

Reference numeral 61 in the figures designates a ring plate installed along the peripheral edge of the bottom surface portion 14 of the container body 12. The ring plate 61 is positioned more outward of the outer periphery of the rotary table 2. In an upper surface of the ring plate 61, a first exhaust port 62 and a second exhaust port 63 are formed in a mutually spaced-apart relationship in the circumferential direction. The first exhaust port 62 is formed between the first process gas nozzle 31 and the separation area D existing at the downstream side of the first process gas nozzle 31 in the rotational direction of the rotary table 2 and is disposed at a position closer to the separation area D. The first exhaust port 62 is configured to exhaust the first process gas and the separation gas. The second exhaust port 63 is formed between the plasma generation gas nozzle 33 and the separation area D existing at the downstream side of the plasma generation gas nozzle 33 in the rotational direction of the rotary table 2 and is disposed at a position closer to the separation area D. The second exhaust port 63 is configured to exhaust the second process gas, the separation gas and the plasma generation gas.

Reference numeral 64 in the figures designates a groove-shaped gas flow path formed in the surface of the ring plate 61. The gas flow path 64 is to guide the second process gas, the separation gas and the plasma generation gas, which flow outward of the rotary table 2, toward the second exhaust port 63. As illustrated in FIG. 1, each of the first exhaust port 62 and the second exhaust port 63 is connected to a vacuum exhaust mechanism, for example, a vacuum pump 67, by an exhaust pipe 66 in which a pressure regulation part 65 such as a butterfly valve or the like is installed.

A control part 100 configured by a computer for controlling the overall operations of the film forming apparatus is installed in the film forming apparatus. A program for performing the below-described film forming process is stored in the control part 100. The program includes step groups which are organized so as to execute the below-described operations of the film forming apparatus. The program is installed into the control part 100 from a memory part 101 which is a storage medium such as a hard disk, a compact disk, a magneto-optical disk, a memory card, a flexible disk or the like.

Next, a film forming process using the film forming apparatus described above will be described. First, the rotary table 2 is heated by the heater unit 16. Then, the gate valve G is opened. With the intermittent rotation of the rotary table 2 and the elevating operation of the lift pins during the stoppage of the rotary table 2, the wafers W loaded in the vacuum container 1 by the transfer mechanism are sequentially mounted on the mounting portions 26 of the respective recess portions 25. The waters W thus mounted are heated to a predetermined temperature, for example, 620 degrees C.

After the wafers W are mounted on the six recess portions 25, the gate valve G is closed and the rotary table 2 rotates clockwise at 20 rpm to 240 rpm, for example, 180 rpm. Then, the N₂ gas is injected at a predetermined flow rate from the separation gas nozzles 41 and 42, the separation gas supply pipe 13 and the purge gas supply pipes 18 and 24. Subsequently, the first process gas and the second process gas are injected from the process gas nozzles 31 and 32, respectively. The plasma generation gas is injected from the plasma generation gas nozzle 33. When the respective gases are injected in this way, the gases are exhausted from the respective exhaust ports 62 and 63 so that an internal pressure of the vacuum container 1 becomes 133 Pa to 1,333 Pa, for example, 1,260 Pa (9.5 Torr), which is a predetermined process pressure. In parallel to the injection and exhaust of the respective gases and the rotation of the rotary table 2, high-frequency power is supplied to the antenna 51 of the plasma generation part 5.

Along with the rotation of the rotary table the first process gas (raw material gas) is adsorbed onto the surface of the wafer W in the first process area P1. Subsequently, the reaction of the first process gas (raw material gas) adsorbed onto the wafer W with the second process gas (reaction gas) occurs in the second process area P2. Thus, one or multiple molecular layers of silicon oxide (SiO₂) as a thin film component are formed and a reaction product is generated. In the meantime, only the magnetic field, among the electric field and the magnetic field generated by the high-frequency power supplied to the antenna 51, passes through the Faraday shield 56 and reaches the interior of the vacuum container 1. Thus, the plasma generation gas is activated to generate plasma (active species) such as, for example, ions or radicals. The reaction product is modified by the plasma. Specifically, as the plasma impinges against the surface of the wafer W, densification occurs due to, for example, the discharge of impurities from the reaction product or the rearrangement of elements within the reaction product.

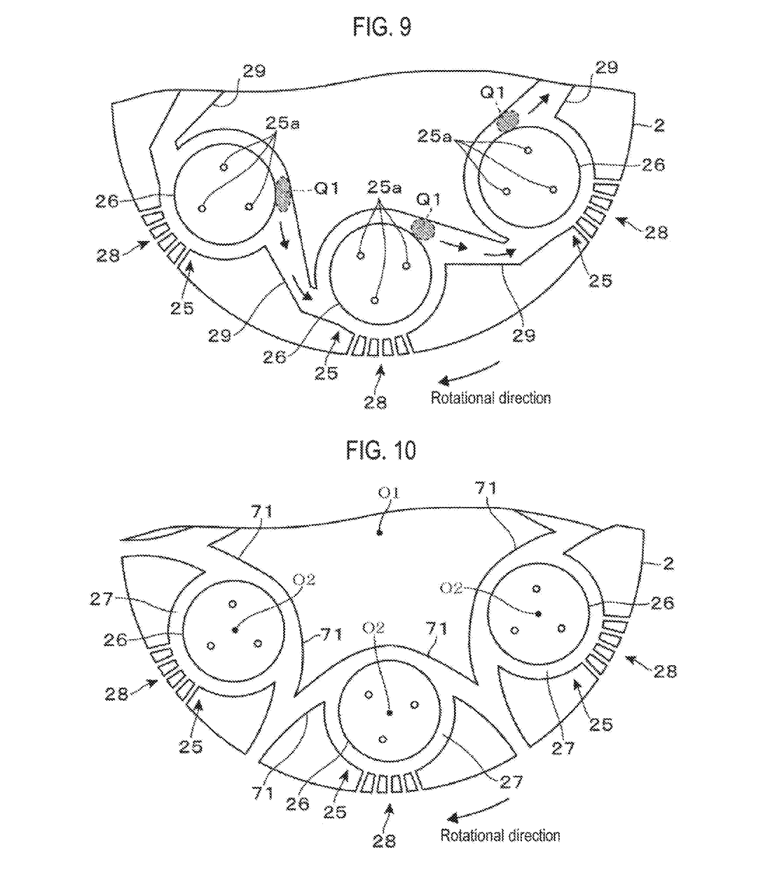

During the forming process, as described with reference to FIGS. 7 and 8, process gas stagnations Q1 are formed in the regions closer to the rotational center O1 of the rotary table 2 than the center O2 of the recess portion 25 in the annular groove portion 27 of each of the recess portions 25, whereby the concentration of the process gas increases in the areas closer to the rotational center O1. However, the process gas, which may otherwise form the process gas stagnations Q1, is guided to the connection groove portion 29. The process gas flows toward the area closer to the peripheral end of the rotary table 2 than the center O2, in which the concentration of the process gas is relatively low, in the annular groove portion 27 of the recess portion 25 adjoining the upstream side of the aforementioned recess portion 25 in the rotational direction. FIG. 9 schematically illustrates flows of the process gas in the connection groove portions 29.

It is considered that the diffusion action attributable to the concentration gradient of the process gas between the one end and the other end of the connection groove portion 29 or the sweeping-away of the process gas stagnations Q1 by the N₂ gas supplied from the separation area D when the recess portion 25 enters the separation area D along with the rotation of the rotary table 2 involves the flow of the process gas in the connection groove portion 29. Due to such a flow of the process gas, the concentration difference in the circumferential direction of annular groove portion 27 is reduced. As a result, it is possible to restrain the concentration of the process gas from becoming higher in some areas of the peripheral edge portion of the water W than in other areas as the process gas goes around the surface of the wafer W from the annular groove portion 27. Accordingly, it is possible to restrain the film thickness from becoming larger in some areas than in other areas.

The process gas flowing into the annular groove portion 27 of the recess portion 25 existing at the upstream side in the rotational direction through the connection groove portion 29 is caused by virtue of the centrifugal force of the rotary table 2 to flow toward the linear groove portions 28 along the rear surface of the wafer W mounted in the recess portion 25 and is exhausted from the linear groove portions 28 outward of the rotary table 2. In addition, the process gas flowing toward the outer periphery of the rotary table 2 along the surface of the wafer W under the centrifugal force of the rotary table 2 is also exhausted from the annular groove portion 27 outward of the rotary table 2.

By continuously rotating the rotary table 2 as described above, the adsorption of the first process gas onto the surface of the wafer W, the production of the reaction product by the reaction of the component of the first process gas adsorbed onto the surface of the wafer W with the second process gas, and the plasma modification of the reaction product, are performed multiple times in the named order, whereby the thickness of the SiO₂ film formed on the surface of the wafer W increases. After the SiO₂ film having a predetermined film thickness is formed, the supply of the respective process gases and the plasma generation gas is stopped. The wafers W are unloaded from the vacuum container 1 through the operation opposite to the operation of loading the wafers W into the vacuum container 1.

According to the film forming apparatus described above, the wafers W are mounted in the mo ting portions 26 within the six recess portions 25 of the rotary table 2, respectively. The recess portions 25 are allowed to sequentially pass through the process areas P1 and P2 to which the process gases are supplied, whereby the film forming process is performed. Furthermore, the connection groove portion 29 communicating with the annular groove portion 27 formed within the other recess portion 25 adjoining the upstream side of one recess portion 25 in the rotational direction is formed to extend from the portion of the annular groove portion 27 which is formed around the mounting portion 26 within one recess portion 25 and which is positioned at the side of the rotational center O1 of the rotary table 2 when viewed fro the center O2 of the mounting portion 26. Thus, the process gas staying in the annular groove portion 27 of one recess portion 25 can flow out toward the connection groove portion 29 and can move toward the area of the groove portion 27 of the other recess portion 25 in which the concentration of the process gas is relatively low. Thus, it is possible to restrain the process gas concentration from locally increasing in the areas of the annular groove portion 27 of the recess portion 25 existing at the side of the rotational center O1 of the rotary table 2. Accordingly, it is possible to restrain the process gas having a high concentration from going around the peripheral edge portion of the surface of the wafer W. This makes it possible to suppress reduction of the film thickness uniformity in the peripheral edge portion of the wafer W.

Furthermore, according to the film forming apparatus described above, the linear groove portions 28 are formed in the edge area of the recess portion 25 so that the process gas moved toward the peripheral end of the rotary table 2 within the recess portion 25 by virtue of the centrifugal force can be exhausted from the recess portion 25. It is therefore possible to reliably prevent generation of areas, in which the concentration of the process gas is locally increased, on the surface of the water W.

Another example of the groove portions for discharging the process gas stagnations Q1 from the annular groove portions 27 is illustrated in FIG. 10. In the rotary table 2 illustrated in FIG. 10, when viewed from the center O2 of each of the recess portions 25 toward the rotational center O1 of the rotary table 2, mutually-spaced-apart areas existing at left and right sides of the front side of the sidewall of the annular groove portion 27 are respectively drawn toward the peripheral end of the rotary table 2, whereby groove portions 71 are formed at left and right sides of each of the recess portions 25. In the recess portions 25 adjoining each other in the rotational direction of the rotary table 2, the right (upstream side in the rotational direction) groove portion 71 of the recess portion 25 existing at the downstream side in the rotational direction and the left (downstream side in the rotational direction) groove portion 71 of the recess portion 25 existing at the upstream side in the rotational direction are merged with each other while extending toward the peripheral end of the rotary table 2. A end portion of the merged groove portions 71 is opened toward the outside of the rotary table 2.

Due to the existence of the groove portions 71 thus formed, the process gas stagnations Q1 formed as described above with reference to FIG. 7 are guided toward the outside of the rotary table 2 and are discharged from the annular groove portion 27. Accordingly, it is possible to obtain the same effects as obtained in the case where the connection groove portions 29 described above are formed in the rotary table 2. The rotary table 2 illustrated in FIG. 10 has the same configuration as the rotary table 2 described with reference to FIG. 3 except that the groove portions 71 are formed in place of the connection groove portions 29.

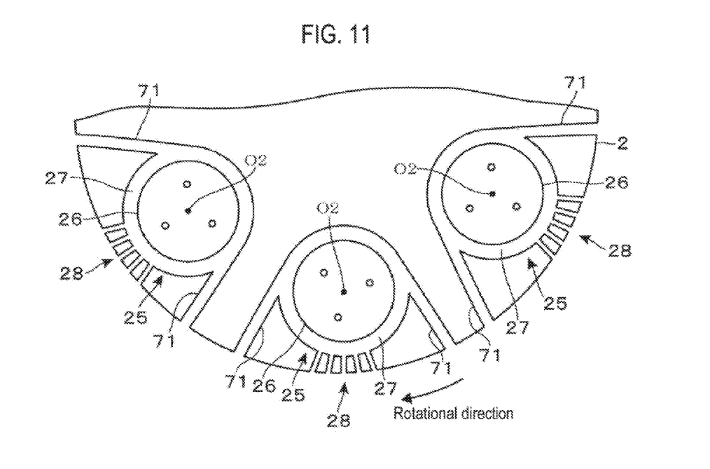

As described above, the external area communicating with one annular groove portion 27 in order to discharge the process gas is not limited to another annular groove portion 27 but may be the outside of the peripheral edge of the rotary table 2. As illustrated in FIG. 11, the groove portions 71 may not be merged with each other on the rotary table 2 and may be formed independently of each other. In other words, the groove portion 71 shared by two mounting portions 26 may be formed as illustrated in FIG. 10, or individual groove portions 71 may be formed in a corresponding relationship with the mounting portions 26 as illustrated in FIG. 11.

The communication path formed in the rotary table 2 in order to discharge the process gas from the annular groove portion 27 to the area existing outside the recess portion 25 is not limited to the groove opened at the upper side thereof but may be a communication hole which interconnects one annular groove portion 27 to another annular groove portion 27 or a communication hole which interconnects one annular groove portion 27 to the outside of the peripheral edge of the rotary table 2. The recess portions 25 may be formed so as to adjoin each other in the radial direction of the rotary table 2. In this case, a connection groove portion 29 may be formed so as to interconnect the recess portions 25 adjoining each other in the radial direction. In addition, the film forming apparatus may be configured no that film formation is performed by chemical vapor deposition (CVD) without separating the areas, to which different kinds of process gases are supplied, by the separation areas D.

### (Evaluation Test)

Next, descriptions will be made on evaluation test 1 conducted in respect of the present disclosure. In evaluation test 1, a film forming process was performed with respect to the wafer W using the film forming apparatus described in the embodiment of the present disclosure. In this film forming process, the temperature of the wafer W was set at 620 degrees C., the rotational speed of the rotary table 2 was set at 180 rpm, the supply amount of the N₂ gas supplied to the central area C was set at 6,000 sccm, the internal pressure of the vacuum container 1 was set at 9.5 Torr (1.27×10³ Pa), and the supply amount of 3DMAS was set at 500 sccm. The film thickness in the respective in-plane portions of the wafer W was measured. In comparative test 1, a film forming process was performed using a film forming apparatus having the same configuration as the film forming apparatus used in evaluation test 1 under the same condition as that of evaluation test 1 except that a rotary table not provided with the connection groove portions 29 is used in place of the rotary table 2. Similar to evaluation test 1, the film thickness in the respective in-plane portions of the wafer W was measured.

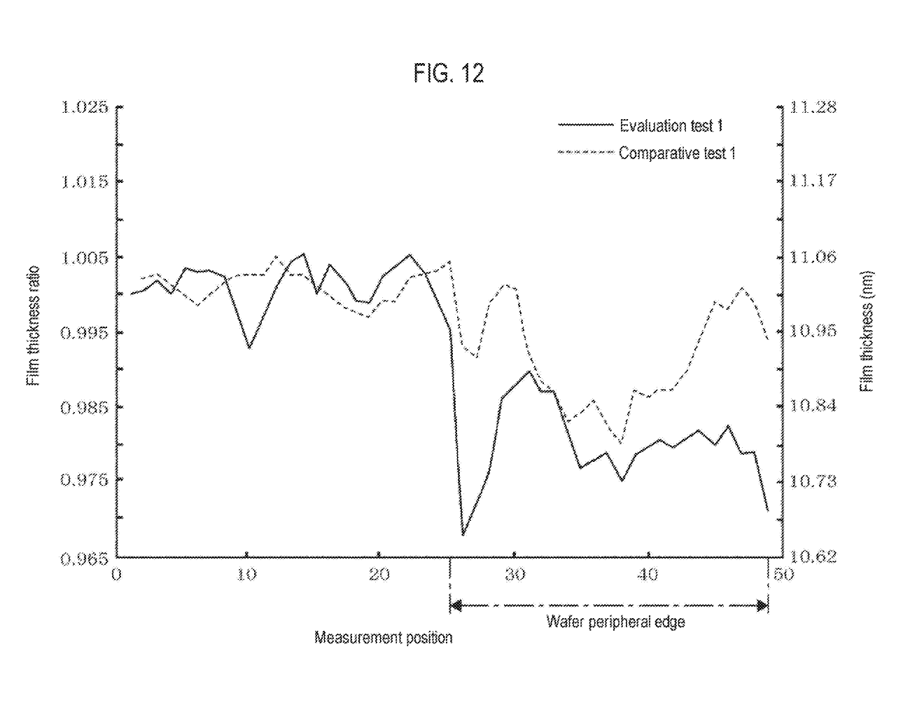

The graph of FIG. 12 shows the results of evaluation test 1 and comparative test 1. The horizontal axis in the graph indicates the film thickness measurement position in terms of numerical values of 1 to 49. The vertical axis in the graph indicates the film thickness ratio and the film thickness (unit: nm). The film thickness ratio indicated in the vertical axis refers to a relative value of the film thickness in the respective portions of the wafer W with respect to the film thickness at the center of the wafer W, which is assumed to be 1. Describing the horizontal axis in more detail, numerical value 1 in the horizontal axis indicates the center of the wafer W. Numerical values 2 to 9 indicate positions on a circumference having a radius of about 50 mm and having a center coinciding with the center of the wafer W. Numerical values 10 to 25 indicate positions on a circumference having a radius of about 100 mm and having a center coinciding with the center of the wafer W. Numerical values 26 to 49 indicate positions on a circumference having a radius of about 150 mm and having a center coinciding with the center of the wafer W. The respective film thickness measurement positions on the same circumference are set so that the distances between the measurement positions adjoining each other in the circumferential direction become equal to each other.

The solid-line curve is a curve obtained by interconnecting plots corresponding to the film thickness acquired in evaluation test 1. The broken-line curve is a curve obtained by interconnecting plots corresponding to the film thickness acquired in comparative test 1. The respective plots are not shown. Referring to the graph, the film thickness measured in the respective positions of numerical values 1 to 25 shows no large difference between evaluation test 1 and comparative test 1. However, referring to the respective positions of numerical values 26 to 49, the film thickness of evaluation test 1 is smaller than the film thickness of comparative test 1 in most of the positions. Accordingly, it is considered that the circulation of the process gas from the annular groove portion 27 to the peripheral edge portion of the surface of the wafer NV is suppressed in evaluation test 1. In particular, in the position of numerical value 29 or so and in the position of numerical value 48 or so, the film thickness ratio measured in comparative test 1 has a value of 1 or more or a value close to 1. In contrast, the film thickness ratio measured in evaluation test 1 has a value far smaller than 1. It can be noted that the circulation of the process gas to the surface of the wafer W can be particularly suppressed in these positions.

Unlike comparative test 1, in evaluation test 1, the film thickness in the position of numerical value 29 or so and the film thickness in the position of numerical value 48 or so are reduced. Thus, the film thickness in the respective positions of numerical values 26 to 49 is smaller than the film thickness in the respective positions of numerical values 1 to 25. In other words, as described in the background section of the present disclosure, it is required that film formation is performed so as to provide a film thickness distribution in which the film thickness in the peripheral edge portion of the wafer is smaller than the film thickness in the central portion of the wafer. In evaluation test 1, film formation is performed so as to provide such a film thickness distribution. The effects of the present disclosure were confirmed from the result of evaluation test 1.

The present disclosure is directed to an apparatus which performs a film forming process by mounting substrates on mounting portions within a plurality of recess portions of a rotary table and allowing the rotary table to sequentially pass through process gas supply areas. A communication path is formed in an annular groove portion existing around each of the mounting portions within each of the recess portions so that the communication path extends from an area of the annular groove portion existing at the rotational center side of the rotary table when viewed from the center of each of the mounting portions, toward an external area of each of the recess portions. For that reason, a gas staying within the annular groove portion formed in each of the recess portions flows out toward the communication path. As a result, it is possible to restrain a concentration of a film forming gas from being locally increased within each of the recess portions. This makes it possible to improve the film thickness uniformity in a circumferential direction of a peripheral edge portion of each of the substrates.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for forming films on a plurality of substrates mounted on a rotary table by rotating the rotary table within a vacuum container and causing the substrates to sequentially pass through areas to which process gases are supplied, comprising:
a plurality of recess portions formed in one surface of the rotary table along a circumferential direction and configured to accommodate the plurality of substrates;
a plurality of mounting portions disposed within the recess portions and configured to support regions of the substrates closer to centers than peripheral edge portions thereof;
a plurality of groove portions formed within the recess portions so as to surround the plurality of mounting portions;
a plurality of communication paths formed so as to extend from regions of the groove portions existing at a side of a rotational center of the rotary table when viewed from a center of each of the plurality of mounting portions, toward an external area of the recess portions, the plurality of communication paths composed of communication grooves or communication holes; and
an exhaust port through which an interior of the vacuum container is vacuum-exhausted,
wherein the external area is an annular groove portion formed around the mounting portion inside the other recess portion adjoining one of the plurality of recess portions or an outside of an outer peripheral edge of the rotary table.

2. The apparatus of claim 1, wherein the external area is the annular groove portion formed around the mounting portion inside the other recess portion adjoining one of the plurality of recess portions and is an area opposite to the rotational center of the rotary table when viewed from a center of the mounting portion inside the other recess portion.

3. The apparatus of claim 1, wherein the other recess portion adjoining one of the plurality of recess portions is the recess portion adjoining one of the plurality of recess portions at an upstream side of a rotational direction of the rotary table during a film forming process when viewed from one of the plurality of recess portions.

4. The apparatus of claim 1, wherein the areas to which process gases are supplied includes a supply area of a raw material gas and a supply area of a reaction gas reacting with the raw material gas, which are spaced apart from each other along a rotational direction of the rotary table, and
separation areas, to which a separation gas is injected toward an upstream side and a downstream side thereof, are formed between the supply area of the raw material gas and the supply area of the reaction gas in order to prevent the raw material gas and the reaction gas from being mixed with each other between the supply area of the raw material gas and the supply area of the reaction gas.

5. The apparatus of claim 1, wherein each of the plurality of communication paths is formed in a wall portion of each of the plurality of recess portions in an edge area of each of the plurality of recess portions opposite to a center of the rotary table when viewed from a center of each of the plurality of recess portions, so as to bring a space existing around the mounting portion of each of the plurality of recess portions into communication with a space existing outside the rotary table.

6. The apparatus of claim 5, wherein when a point where a straight line interconnecting the center of each of the plurality of recess portions and the rotational center of the rotary table intersects an outer periphery of the rotary table is assumed to be P, the edge area of each of the plurality of recess portions is an area between straight lines which form an opening angle of 30 degrees from the center of each of the plurality of recess portions to left and right sides of the point P.
